(19) United States
(12) Patent Application Publication
(10) Pub. No.: US 2025/0222559 A1
(43) Pub. Date: Jul. 10, 2025

(54) INFORMATION PROCESSING APPARATUS, INFERENCE APPARATUS, MACHINE-LEARNING APPARATUS, INFORMATION PROCESSING METHOD, INFERENCE METHOD, AND MACHINE-LEARNING METHOD

(71) Applicant: EBARA CORPORATION, Tokyo (JP)

(72) Inventors: Kenichi TAKEBUCHI, Tokyo (JP); Kenichiro SAITO, Tokyo (JP)

(21) Appl. No.: 18/850,504

(22) PCT Filed: Mar. 2, 2023
(86) PCT No.: PCT/JP2023/007774

§ 371 Date: Sep. 24, 2024

(30) Foreign Application Priority Data
Mar. 30, 2022 (JP) 2022-056743

(51) Int. Cl. B24B 53/017; B24B 49/10; B24B 49/14

(52) U.S. Cl. CPC B24B 53/017; B24B 49/10; B24B 49/14

(57) ABSTRACT

The information processing apparatus (5) includes an information acquisition section (500) configured to acquire operating condition information including top-ring state information, polishing-table state information, polishing-fluid-supply-nozzle state information, dresser state information, and atomizer state information, as operating conditions under which a substrate processing apparatus performs operation of chemical mechanical polishing of a substrate. The information processing apparatus (5) further includes a state prediction section (501) configured to predict polishing-pad state information for the operating condition information by inputting the operating condition information acquired by the information acquisition section (500) to a learning model (10A) that has been generated by machine learning that causes the learning model (10A) to learn a correlation between the operating condition information and the polishing-pad state information.

### Technical Field

The present invention relates to an information processing apparatus, an inference apparatus, a machine-learning apparatus, an information processing method, an inference method, and a machine-learning method.

### Background Art

A substrate processing apparatus that performs chemical mechanical polishing (CMP) is known as a type of substrate processing apparatuses that performs various processing on a substrate, such as a semiconductor wafer. In the substrate processing apparatus, for example, a substrate is chemically and mechanically polished by pressing the substrate against a polishing pad by a polishing head, which is referred to as a top ring, with a polishing liquid (e.g., slurry) being supplied onto the polishing pad from a polishing-fluid supply nozzle, while a polishing table having the polishing pad is being rotated. Then, dressing of the polishing pad is performed by a dresser, and a high-pressure cleaning fluid is then supplied to the polishing pad from an atomizer to remove polishing debris remaining on the polishing pad, so that a series of processes is completed. The next substrate is then processed.

Since wear of the polishing pad gradually progresses as the above-described series of processes is repeated, it is necessary to replace the polishing pad. A replacement time of the polishing pad has been managed based on, for example, an accumulated use time of the polishing pad (for example, see Patent document 1).

### CITATION LIST

### Patent Literature

Patent document 1: Japanese laid-open patent publication No. 2011-204721

### SUMMARY OF INVENTION

### Technical Problem

In Patent document 1, the accumulated use time of the polishing pad is determined by accumulating time during which the top ring presses the substrate against the polishing pad to polish the substrate. However, a state of the polishing pad varies not only during polishing of the substrate performed by the top ring, but also during dressing of the polishing pad performed by the dresser or cleaning of the polishing pad performed by the atomizer. Therefore, the state of the polishing pad cannot be determined in detail only by the management of the accumulated use time.

On the other hand, operating conditions of the top ring, the polishing table, the polishing-fluid supply nozzle, the dresser, and the atomizer included in the substrate processing apparatus are factors that affect the state of the polishing pad. These operating conditions act Therefore, it is difficult to accurately analyze the complexly and mutually on the polishing pad. effects of the respective operating conditions on the state of the polishing pad.

In view of the above-mentioned drawbacks, it is an object of the present invention to provide an information processing apparatus, an inference apparatus, a machine-learning apparatus, an information processing method, an inference method, and a machine-learning method capable of appropriately predicting a state of a polishing pad according to operating conditions of a substrate processing apparatus.

### Solution to Problem

In order to achieve the above object, an information processing device according to an embodiment of the present invention, comprises:
an information acquisition section configured to acquire operating condition information and atomizer state information indicating a state of an atomizer as operating conditions under which a substrate processing apparatus operates, the operating condition information including top-ring state information indicating a state of a top ring, polishing-table state information indicating a state of a polishing table, polishing-fluid-supply-nozzle state information indicating a state of a polishing-fluid supply nozzle, and dresser state information indicating a state of a dresser, the substrate processing apparatus being configured to perform chemical mechanical polishing of a substrate and including the polishing table configured to rotatably support a polishing pad, the top ring configured to press the substrate against the polishing pad, the polishing-fluid supply nozzle configured to supply a polishing fluid onto the polishing pad, the dresser configured to rotatably support a dresser disk and bring the dresser disk into contact with the polishing pad to dress the polishing pad, and the atomizer configured to emit a cleaning fluid to the polishing pad; and
a state prediction section configured to predict polishing-pad state information for the operating condition information by inputting the operating condition information acquired by the information acquisition section to a learning model that has been generated by machine learning that causes the learning model to learn a correlation between the operating condition information and the polishing-pad state information indicating a state of the polishing pad when the substrate processing apparatus operates under the operating conditions indicated by the operating condition information.

### Advantageous Effects of Invention

According to the information processing apparatus of the embodiment of the present invention, the operating condition information including the top-ring state information, the polishing-table state information, the polishing-fluid-supply-nozzle state information, the dresser state information, and the atomizer state information is input to the learning model, so that the polishing-pad state information for the operating condition information can be predicted. Therefore, the state of the polishing pad can be predicted appropriately according to the operating conditions of the substrate processing apparatus.

Objects, configurations, and effects other than those described above will be made clear in detailed descriptions of the invention described below.

### BRIEF DESCRIPTION OF DRAWINGS

FIG. 1 is an overall configuration diagram showing an example of a substrate processing system 1;

FIG. 2 is a plan view showing an example of a substrate processing device 2;

FIG. 3 is a perspective view showing an example of first to fourth polishing sections 22A to 22D;

FIG. 4 is a cross-sectional view schematically showing an example of a top ring 221;

FIG. 5 is a block diagram showing an example of the substrate processing device 2;

FIG. 6 is a hardware configuration diagram showing an example of a computer 900;

FIG. 7 is a data configuration diagram showing an example of production history information 30 managed by a database device 3;

FIG. 8 is a data configuration diagram showing an example of polishing-test information 31 managed by the database device 3;

FIG. 9 is a block diagram showing an example of a machine-learning device 4 according to a first embodiment;

FIG. 10 is a diagram showing an example of a first learning model 10A and first learning data 11A;

FIG. 11 is a flowchart illustrating an example of a machine-learning method performed by the machine-learning device 4;

FIG. 12 is a block diagram showing an example of an information processing device 5 according to the first embodiment;

FIG. 13 is a functional explanatory diagram showing an example of the information processing device 5 according to the first embodiment;

FIG. 14 is a flowchart illustrating an example of an information processing method performed by the information processing device 5;

FIG. 15 is a block diagram showing an example of a machine-learning device 4a according to a second embodiment;

FIG. 16 is a diagram showing an example of a second learning model 10B and second learning data 11B;

FIG. 17 is a block diagram showing an example of an information processing device 5a functioning as the information processing device 5a according to the second embodiment; and

FIG. 18 is a functional explanatory diagram showing an example of the information processing device 5a according to the second embodiment.

### DESCRIPTION OF EMBODIMENTS

Embodiments for practicing the present invention will be described below with reference to the drawings. In the following descriptions, scope necessary for the descriptions to achieve the object of the present invention will be schematically shown, scope necessary for the descriptions of relevant parts of the present invention will be mainly described, and parts omitted from the descriptions will be based on known technology.

### First Embodiment

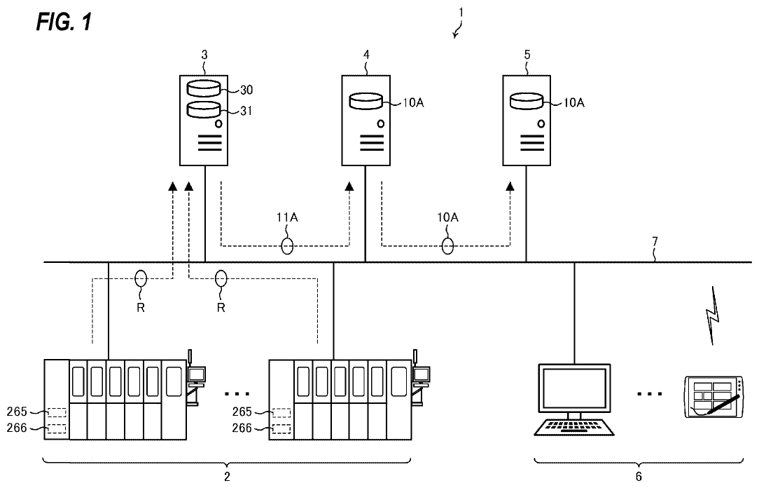

FIG. 1 is an overall configuration diagram showing an example of a substrate processing system 1. The substrate processing system 1 according to this embodiment functions as a system configured to manage a series of substrate processes including a chemical mechanical polishing (hereinafter referred to as “polishing process”) of planarizing a surface of a substrate (hereinafter referred to as a “wafer”) W, such as a semiconductor wafer, and a cleaning process of cleaning the surface of the wafer W after polishing by bringing the wafer W into contact with a cleaning tool.

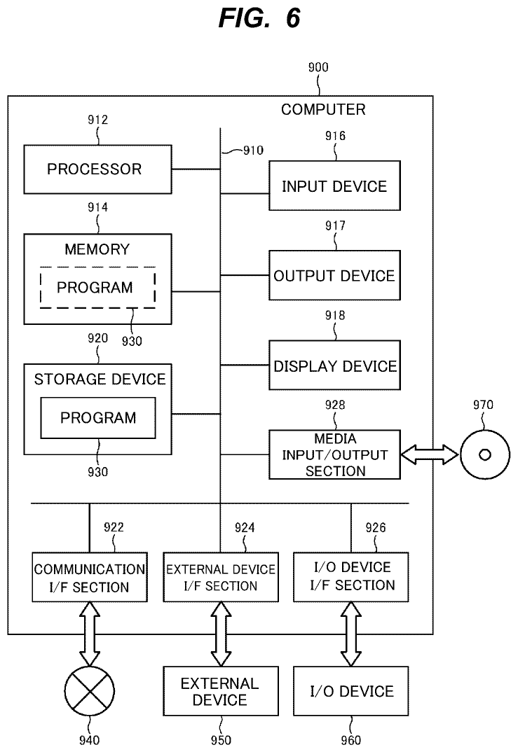

The substrate processing system 1 includes, as its main components, substrate processing devices 2, a database device 3, a machine-learning device 4, an information processing device 5, and a user terminal device 6. Each of the devices 2 to 6 is configured with, for example, a general-purpose computer or dedicated computer (see FIG. 6 described later). The devices 2 to 6 are coupled to a wired or wireless network 7 so as to be able to transmit and receive various data (some data are shown in FIG. 1 with dotted arrows). The number of devices 2 to 6 and the connection configuration of the network 7 are not limited to the example shown in FIG. 1, and may be changed as appropriate.

Each substrate processing device 2 is composed of a plurality of units and is configured to perform a series of substrate processes on one or more wafers W, such as loading, polishing, cleaning, drying, film-thickness measuring, and unloading. During the processes, the substrate processing device 2 controls operations of the units while referring to device setting information 265 including device parameters that have been set for the units and substrate recipe information 266 that determines operating conditions in the polishing process, the cleaning process, and the drying process.

The substrate processing device 2 is configured to transmit various reports R to the database device 3, the user terminal device 6, etc. according to the operation of each unit. The various reports R include, for example, process information that identifies a wafer W on which substrate processing is performed, device-state information that indicates a state of each unit when each process is performed, event information detected by the substrate processing device 2, and manipulation information of a user (an operator, a production manager, a maintenance manager, etc.) on the substrate processing device 2.

The database device 3 is an apparatus that manages production history information 30 on a history when substrate processing is performed using a polishing pad for proper production, and polishing-test information 31 on a history of a test of polishing processing (hereinafter referred to as “polishing test”) using a polishing pad for test. In addition to the above information, the database device 3 may also store the device setting information 265 and the substrate recipe information 266. In that case, the substrate processing device 2 may refer to these information.

The database device 3 receives various reports R from the substrate processing device 2 when the substrate processing device 2 has performed the substrate processing using the polishing pad for proper production, and registers the various reports R in the production history information 30, so that the reports R on the substrate processing are accumulated in the production history information 30.

When the substrate processing device 2 performs the polishing test using the polishing pad for test, the database device 3 receives the various reports R (including at least device state information) from the substrate processing device 2, registers the reports R in the polishing-test information 31, and registers test results of the polishing test associated with the various reports R, so that the reports R and the test results on the polishing test are accumulated in the polishing-test information 31. The polishing test may be performed by the substrate processing device 2 for proper production, or may be performed by a polishing-test device (not shown) for testing capable of performing the same polishing process as that of the substrate processing device 2. Various polishing-pad measuring devices (not shown) are disposed at the polishing pad for test or the polishing-test device and are configured to measure conditions of the polishing pad including, for example, a distribution state of polishing debris present on a polishing surface of the polishing pad, a flatness, a surface roughness, a temperature, a wetness, and a friction coefficient of the polishing surface. Measurement values of the polishing-pad measuring devices are registered as the test results in the polishing-test information 31.

The machine-learning device 4 operates as a main configuration for a learning phase in machine learning. For example, the machine-learning device 4 acquires, as first learning data 11A, part of the polishing-test information 31 from the database device 3, and performs the machine learning to create a first learning model 10A to be used in the information processing device 5. The first learning model 10A as a learned model is provided to the information processing device 5 via the network 7, a storage medium, or the like.

The information processing device 5 operates as a main configuration for an inference phase in the machine learning. When the polishing process is performed using a polishing pad for proper production by the substrate processing device 2, the information processing device 5 predicts a state of the polishing pad using the first learning model 10A created by the machine-learning device 4, and transmits polishing-pad state information, which is a result of the prediction, to the database device 3, the user terminal device 6, etc. The timing at which the information processing device 5 predicts the polishing-pad state information may be after the polishing process (i.e., post-predicting process), during the polishing process (i.e., real-time-predicting process), or before the polishing process (i.e., pre-predicting process).

The user terminal device 6 is a terminal device used by a user. The user terminal device 6 may be a stationary device or a portable device. The user terminal device 6 receives various input manipulations via a display screen of an application program, a web browser, etc., and displays various information (e.g., a notification of event, the polishing-pad state information, the production history information 30, the polishing-test information 31, etc.) via the display screen.

### Substrate Processing Device 2

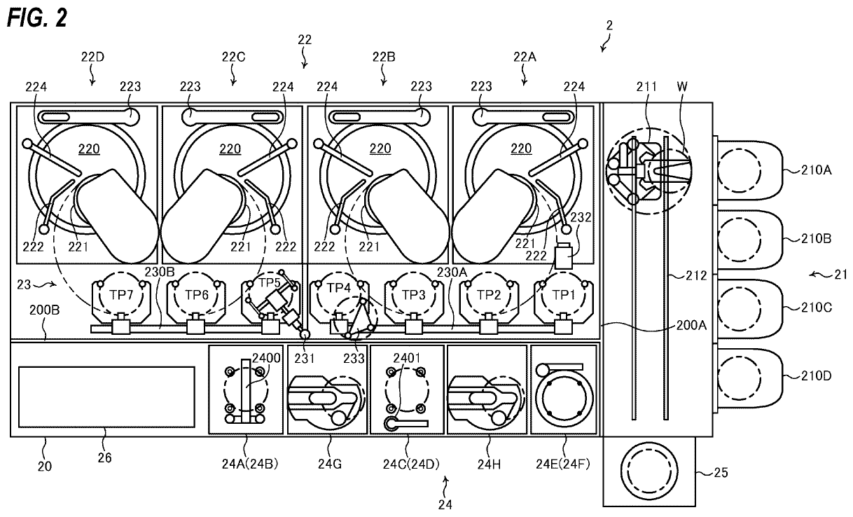

FIG. 2 is a plan view showing an example of the substrate processing device 2. The substrate processing device 2 includes a load-unload unit 21, a polishing unit 22, a substrate transport unit 23, a finishing unit 24, a film-thickness measuring unit 25, and a control unit 26 which are arranged inside a housing 20 that is substantially rectangular in a plan view. The load-unload unit 21 is isolated from the polishing unit 22, the substrate transport unit 23, and the finishing unit 24 by a first partition wall 200A. The substrate transport unit 23 is isolated from the finishing unit 24 by a second partition wall 200B.

### Load-Unload Unit

The load-unload unit 21 includes first to fourth front load sections 210A to 210D on which wafer cassettes (FOUPs, etc.), each capable of storing a large number of wafers W along a vertical direction, are placed, a transfer robot 211 that is movable along the storage direction (vertical direction) of the wafers W in each wafer cassette, and a horizontally-moving mechanism 212 for moving the transfer robot 211 along an arrangement direction of the first to fourth front load sections 210A to 210D (i.e., along a direction of a shorter side of the housing 20).

The transfer robot 211 is configured to be accessible to the wafer cassette placed on each of the first to fourth front load sections 210A to 210D, the substrate transport unit 23 (specifically, a lifter 232, which will be described later), the finishing unit 24 (specifically, first and second drying section 24E, 24F, which will be described later), and the film-thickness measuring unit 25. The transfer robot 211 includes upper and lower hands (not shown) for transporting the wafer W between the wafer cassette, the substrate transport unit 23, the finishing unit 24, and the film-thickness measuring unit 25. The lower hand is used when transporting the wafer W before processing of the wafer W, and the upper hand is used when transporting the wafer W after processing of the wafer W. When the wafer W is transported to and from the substrate transport unit 23 or the finishing unit 24, a shutter (not shown) provided on the first partition wall 200A is opened and closed.

### Polishing Unit

The polishing unit 22 includes first to fourth polishing sections 22A to 22D each configured to perform the polishing process (planarization) on the wafer W. The first to fourth polishing sections 22A to 22D are arranged in parallel along the longitudinal direction of the housing 20.

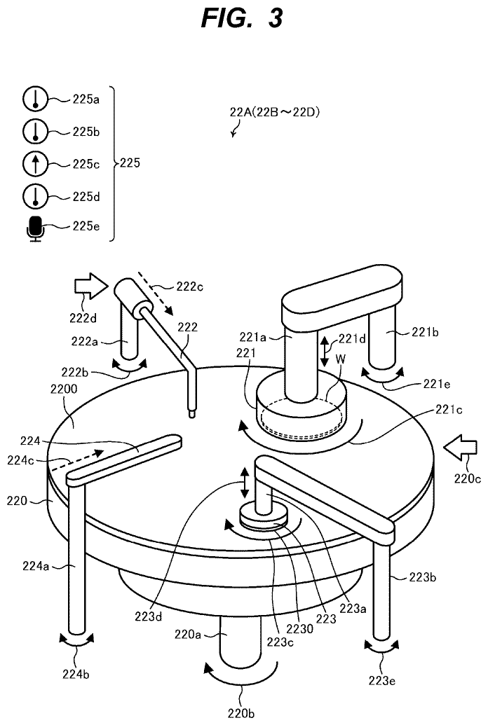

FIG. 3 is a perspective view showing an example of the first to fourth polishing sections 22A to 22D. The first to fourth polishing sections 22A to 22D have common basic configurations and functions.

Each of the first to fourth polishing sections 22A to 22D includes a polishing table 220 that rotatably supports a polishing pad 2200 having a polishing surface, a top ring (polishing head) 221 configured to hold the wafer W and to polish the wafer W while pressing the wafer W against the polishing pad 2200 on the polishing table 220, a polishing-fluid supply nozzle 222 configured to supply a polishing fluid onto the polishing pad 2200, a dresser 223 that rotatably supports a dresser disk 2230 and configured to dress the polishing pad 2200 by bringing the dresser disk 2230 into contact with the polishing surface of the polishing pad 2200, an atomizer 224 configured to emit a cleaning fluid to the polishing pad 2200, and an environment sensor 225 configured to measure a state of an internal space of the housing 20 where the polishing process is performed.

The polishing table 220 is supported by a polishing table shaft 220a. The polishing table 220 includes a rotating mechanism 220b configured to rotate the polishing table 220 about its own axis, and a temperature regulating mechanism 220c configured to regulate a surface temperature of the polishing pad 2200.

The top ring 221 is supported by a top-ring shaft 221a that is movable in the vertical direction. The top ring 221 includes a rotating mechanism 221c configured to rotate the top ring 221 about an axis of the top ring 221, a vertical movement mechanism 221d configured to move the top ring 221 in the vertical direction, and an oscillation mechanism 221e configured to rotate (or oscillate) the top ring 221 around a support shaft 221b as a pivot center.

The polishing-fluid supply nozzle 222 is supported by a support shaft 222a. The polishing-fluid supply nozzle 222 includes an oscillation mechanism 222b configured to rotate and move the polishing-fluid supply nozzle 222 around the support shaft 222a as a pivot center, a flow-rate regulator 222c configured to regulate a flow rate of the polishing fluid, and a temperature regulating mechanism 222d configured to regulate a temperature of the polishing fluid. The polishing fluid is a polishing liquid (e.g., slurry) or pure water, which may further include a chemical liquid, or may be a polishing liquid to which a dispersant is added.

The dresser 223 is supported by a dresser shaft 223a that is movable in the vertical direction. The dresser 223 includes a rotating mechanism 223c configured to rotate about its own axis, a vertical movement mechanism 223d configured to move the dresser 223 in the vertical direction, and an oscillation mechanism 223e configured to rotate and move the dresser 223 around a support shaft 223b as a pivot center.

The atomizer 224 is supported by a support shaft 224a. The atomizer 224 includes an oscillation mechanism 224b configured to rotate and move the atomizer 224 around the support shaft 224a as a pivot center, and a flow-rate regulator 224c configured to regulate a flow rate of the cleaning fluid. The polishing fluid is a polishing liquid (e.g., slurry) or pure water, which may further include a chemical liquid, or may be a polishing liquid to which a dispersant has is added.

The environment sensor 225 is constituted of sensors arranged in the internal space of the housing 20. The environment sensor 225 includes, for example, a temperature sensor 225a configured to measure temperature of the internal space, a humidity sensor 225b configured to measure humidity of the internal space, an atmospheric-pressure sensor 225c configured to measure atmospheric pressure of the internal space, an oxygen-concentration sensor 225d, and a microphone (sound sensor) 225e. The environment sensor 225 may include a camera (image sensor) configured to be able to generate an image of a surface of the polishing pad 2200, an image of temperature distribution, an image of air-flow distribution or the like during, before, or after the polishing process. The object of the camera is not limited to visible light, and may be infrared light, ultraviolet light, etc.

In FIG. 3, specific configurations of the rotating mechanisms 220b, 221c, 223c, the vertical movement mechanisms 221d, 223d, and the oscillation mechanisms 221e, 222b, 223e, 224b are omitted, but each mechanism may be constructed by appropriately combining module for generating driving force (e.g., motor, air cylinder), driving force transmission mechanism (e.g., linear guide, ball screw, gear, belt, coupling, bearing, and sensor (e.g., linear sensor, encoder sensor, limit sensor, torque sensor). In FIG. 3, specific configurations of the flow-rate regulator 222c and 224c are omitted, but the flow-rate regulator 222c and 224c may be constructed by appropriately combining module for regulating a flow rate (e.g., pump, valve, a regulator), and sensor (e.g., flow-rate sensor, pressure sensor, liquid-level sensor, temperature sensor, fluid-concentration sensor, fluid particle sensor). In FIG. 3, specific configurations of the temperature regulating mechanisms 220c and 222d are omitted, but the temperature regulating mechanisms 220c and 222d may be constructed by appropriately combining (contact or non-contact) module for regulating temperature (e.g., heater, heat exchanger), and sensor, (e.g., temperature sensor, current sensor).

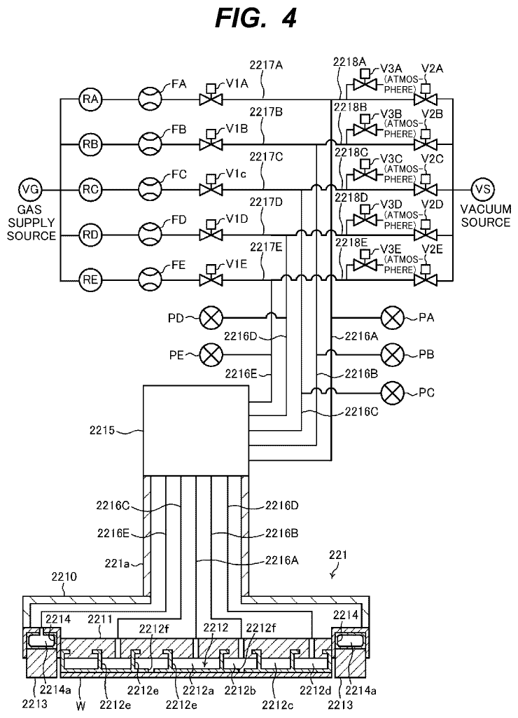

FIG. 4 is a cross-sectional view schematically showing an example of the top ring 221. The top ring 221 includes a top ring body 2210 attached to the top ring shaft 221a, a substantially disc-shaped carrier 2211 arranged in the top ring body 2210, a membrane 2212 arranged beneath the carrier 2211 and configured to press the wafer W against the polishing pad 2200, a substantially annular retainer ring 2213 that is disposed at peripheries of the carrier 2211 and the membrane 2212 and configured to directly press the polishing pad 2200, and a retainer-ring airbag 2214 arranged between the top ring body 2210 and the retainer ring 2213 and configured to press the retainer ring 2213 against the polishing pad 2200.

The membrane 2212 is an elastic membrane, and has a plurality of concentric partition walls 2212e therein that form four membrane pressure chambers 2212a to 2212d arranged concentrically from the center toward the circumference of the top ring body 2210. Further, the membrane 2212 has a plurality of holes 2212f for attracting the wafer W to a lower surface of the membrane 2212, and functions as a substrate holding surface for holding the wafer W. The retainer-ring airbag 2214 is formed of an elastic membrane and has a retaining-ring pressure chamber 2214a therein. The configurations of the top ring 221 may be changed as appropriate, and the top ring 221 may have a pressure chamber that presses the entire carrier 2211. The number and shape of the membrane pressure chambers of the membrane 2212 may be changed as appropriate. The number and arrangement of the suction holes 2212f may be changed as appropriate. Furthermore, the membrane 2212 may not have the suction holes 2212f.

First to fourth flow paths 2216A to 2216D are coupled to the first to fourth membrane pressure chambers 2212a to 2212d, respectively, and a fifth flow path 2216E is coupled to the retaining-ring pressure chamber 2214a. The first to fifth flow paths 2216A to 2216E communicate with an exterior via a rotary joint 2215 provided on the top ring shaft 221a. The first to fifth flow paths 2216A to 2216E are divided into first branch paths 2217A to 2217E and second branch paths 2218A to 2218E. Pressure sensors PA to PE are installed in the first to fifth flow paths 2216A to 2216E, respectively. The first branch paths 2217A to 2217E are coupled to a gas supply source GS of pressurized fluid (air, nitrogen, etc.) via valves V1A to V1E, flow-rate sensors FA to FE, and pressure regulators RA to RE. The second branch paths 2218A to 2218E are coupled to a vacuum source VS via valves V2A to V2E, respectively, and are configured to be able to communicate with the atmosphere via valves V3A to V3E.

The wafer W is attracted and held on the lower surface of the top ring 221 and is moved to a predetermined polishing position above the polishing table 220. Thereafter, the wafer W is polished by being pressed by the top ring 221 against the polishing surface of the polishing pad 2200 on which the polishing fluid is suppled from the polishing-fluid supply nozzle 222. At this time, the top ring 221 controls the pressure regulators RA to RE independently to generate pressing forces that press the wafer W against the polishing pad 2200 via the pressurized fluid supplied to the first to fourth membrane pressure chambers 2212a to 2212d while adjusting the pressing forces for respective regions of the wafer W. A pressing force for pressing the retainer ring 2213 against the polishing pad 2200 is adjusted by the pressurized fluid supplied to the retainer-ring pressure chamber 2214a. The pressures of the pressurized fluid supplied to the first to fourth membrane pressure chambers 2212a to 2212d and the retaining-ring pressure chamber 2214a are measured by the pressure sensors PA to PE, respectively, and the flow rates of the pressurized gas are measured by the flow-rate sensors FA to FE, respectively.

### Substrate Transport Unit

As shown in FIG. 2, the substrate transport unit 23 includes first and second linear transporters 230A, 230B that are horizontally movable along the arrangement direction of the first to fourth polishing sections 22A to 22D (i.e., the longitudinal direction of the housing 20), a swing transporter 231 arranged between the first and second linear transporters 230A, 230B, a lifter 232 arranged near the load-unload unit 21, and a temporary station 233 for the wafer W arranged near the finishing unit 24.

The first linear transporter 230A is arranged adjacent to the first and second polishing sections 22A and 22B and is configured to transport the wafer W to four transfer positions (which will be referred to as first to fourth transfer positions TP1 to TP4 in the order from the load-unload-unit-21-side). The second transfer position TP2 is a position where the wafer W is delivered to the first polishing section 22A, and the third transfer position TP3 is a position where the wafer W is delivered to the second polishing section 22B.

The second linear transporter 230B is arranged adjacent to the third and fourth polishing sections 22C and 22D and is configured to transport the wafer W to three transfer positions (which will be referred to as fifth to seventh transfer positions TP5 and TP7 in the order from the load-unload-unit-21-side). The sixth transfer position TP6 is a position where the wafer W is delivered to the third polishing section 22C, and the seventh transfer position TP7 is a position where the wafer W is delivered to the fourth polishing section 22D.

The swing transporter 231 is disposed adjacent to the fourth and fifth transfer positions TP4 and TP5. The swing transporter 231 has a hand that is movable between the fourth and fifth transfer positions TP4 and TP5. The swing transporter 231 is configured to transport the wafer W between the first and second linear transporters 230A and 230B and place the wafer W temporarily on the temporary station 233. The lifter 232 is disposed adjacent to the first transfer position TP1. The lifter 232 is configured to transport the wafer W between the first transfer position TP1 and the transfer robot 211 of the load-unload unit 21. When the wafer W is transported, the shutter (not shown) provided on the first partition wall 200A is opened and closed.

### Finishing Unit

As shown in FIG. 2, the finishing unit 24 includes a substrate cleaning device using roll sponge 2400 that includes first and second roll sponge cleaning sections 24A and 24B arranged in upper and lower stages. The finishing unit 24 further includes a substrate cleaning device using pen sponge 2401 that includes first and second pen sponge cleaning sections 24C and 24D arranged in upper and lower stages. The finishing unit 24 further includes a substrate drying device for dying the cleaned wafer W that includes first and second drying sections 24E and 24F arranged in upper and lower stages. The finishing unit 24 further includes first and second transport sections 24G and 24H configured to transport the wafer W. It is noted that the number and arrangement of the roll sponge cleaning sections 24A, 24B, the pen sponge cleaning sections 24C, 24D, the drying sections 24E, 24F, and the transport sections 24G, 24H are not limited to the example in FIG. 2, and may be changed as appropriate. For example, the positions of the roll sponge cleaning sections 24A, 24B and the pen sponge cleaning sections 24C, 24D may be switched.

The sections 24A to 24H of the finishing unit 24 are isolated from each other and are arranged along the first and second linear transporters 230A and 230B, for example, in an order of the first and second roll sponge cleaning sections 24A, 24B, the first transport section 24G, the first and second pen sponge cleaning sections 24C, 24D, the second transport section 24H, and the first and second drying sections 24E, 24F (in an order of distance from the load-unload unit 21). The finishing unit 24 sequentially performs a primary cleaning process on the wafer W after the polishing process using one or both of the first and second roll sponge cleaning sections 24A and 24B, a secondary cleaning process on the wafer W using one or both of the first and second pen sponge cleaning sections 24C and 24D, and a drying process on the wafer W using one or both of the first and second drying sections 24E and 24F. The order of the processes performed by the sections 24A to 24H of the finishing unit 24 may be changed as appropriate, or some of the processes may be omitted. For example, the cleaning process performed by the roll sponge cleaning sections 24A and 24B may be omitted, and the processes may be started from the cleaning process performed by the pen sponge cleaning sections 24C and 24D. The finishing unit 24 may include a buff cleaning section (not shown) instead of or in addition to any of the roll sponge cleaning sections 24A and 24B and the pen sponge cleaning sections 24C and 24D, and may perform a buff cleaning process. In this embodiment, each of the sections 24A to 24H of the finishing unit 24 holds the wafer W in a horizontal posture (horizontally holds the wafer W), while each of the sections 24A to 24H may vertically hold or obliquely hold the wafer W.

### Film-Thickness Measuring Unit

The film-thickness measuring unit 25 is a measuring device that measures the film thickness of the wafer W before or after the polishing process. The film-thickness measuring unit 25 is, for example, an optical film-thickness measuring device, an eddy current type film-thickness measuring device, or the like. The transfer robot 211 transports the wafer W to and from each film-thickness measuring module.

### Control Unit

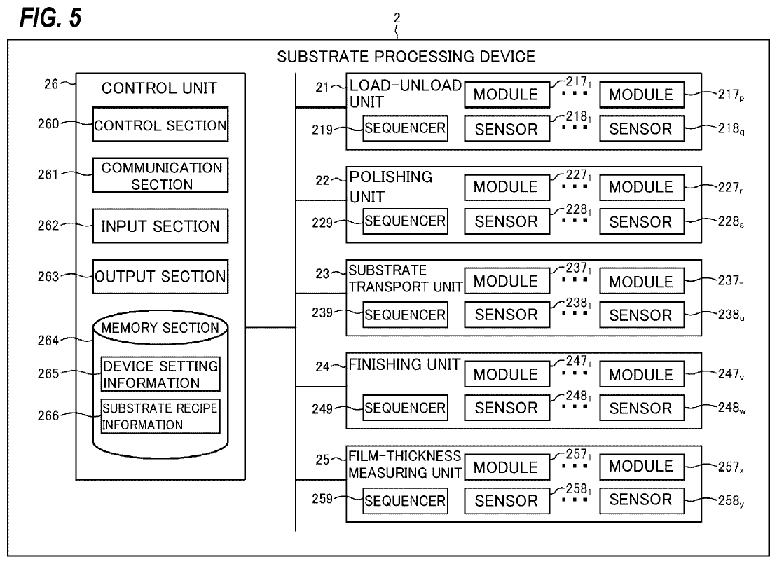

FIG. 5 is a block diagram showing an example of the substrate processing device 2. The control unit 26 is electrically coupled to each of the units 21 to 25, and functions as a control section that comprehensively controls the units 21 to 25. In this embodiment, a control system (i.e., modules, sensors, and a sequencer) of the polishing unit 22 will be described as an example. Control systems of the other units 21, and 23 to 25 have common basic configurations and functions, and descriptions will be omitted.

The polishing unit 22 includes modules 2271 to 227r to be controlled, which are disposed in sub-units (e.g., the polishing table 220, the top ring 221, the polishing-fluid supply nozzle 222, the dresser 223, the atomizer 224) of the polishing unit 22, respectively, sensors 2281 to 228s arranged in modules 2271 to 227r, respectively, for detecting data (i.e., detection values) necessary for controlling the modules 2271 to 227r, and a sequencer 229 for controlling the operations of the modules 2271 to 227r based on the detection values obtained by the sensors 2281 to 228s.

Examples of the sensors 2281 to 228s of the polishing unit 22 may include a sensor configured to detect a rotation speed of the polishing table 220, a sensor configured to detect a rotation torque of the polishing table 220, a sensor configured to detect a surface temperature of the polishing pad 2200, a sensor configured to detect a rotation speed of the top ring 221, a sensor configured to detect a rotation torque of the top ring 221, a sensor configured to detect an oscillation position of the top ring 221, a sensor configured to detect an oscillation speed of the top ring 221, a sensor configured to detect an oscillation torque of the top ring 221, a sensor configured to detect a height of the top ring 221, a sensor configured to detect an elevating torque of the top ring 221, sensors configured to detect pressures (positive pressure and negative pressure) in the first to fourth membrane pressure chambers 2212a to 2212d and the retainer-ring pressure chamber 2214a, sensors configured to detect flow rates of the pressurized fluid supplied to the first to fourth membrane pressure chambers 2212a to 2212d and the retainer-ring pressure chamber 2214a, a sensor configured to detect a flow rate of the polishing fluid supplied from the polishing-fluid supply nozzle 222, a sensor configured to detect a temperature of the polishing fluid supplied from the polishing-fluid supply nozzle 222, a sensor configured to detect an oscillation position of the polishing-fluid supply nozzle 222 that can be converted to a dropping position of the polishing fluid supplied by the polishing-fluid supply nozzle 222, a sensor configured to detect a concentration of the polishing fluid, a sensor configured to detect a cleanliness of the polishing fluid (e.g., a concentration, a particle diameter, or the number of particles for each particle diameter of particles contained in a waste liquid of the polishing fluid), a sensor configured to detect a rotation speed of the dresser 223, a sensor configured to detect a rotation torque of the dresser 223, a sensor configured to detect an oscillation position of the dresser 223, a sensor configured to detect an oscillation speed of the dresser 223, a sensor configured to detect an oscillation torque of the dresser 223, a sensor configured to detect a height of the dresser 223, a sensor configured to detect a pressing load when the dresser disk 2230 is brought into contact with the polishing pad, a sensor configured to detect a flow rate of the cleaning fluid supplied from the atomizer 224, a sensor configured to detect a temperature of the cleaning fluid supplied from the atomizer 224, a sensor configured to detect a pressure of the cleaning fluid supplied from the atomizer 224, a sensor configured to detect an oscillation position of the atomizer 224 that can be converted to a dropping position of the cleaning fluid supplied by the atomizer 224, and the environment sensor 225, etc.

The control unit 26 includes a control section 260, a communication section 261, an input section 262, an output section 263, and a memory section 264. The control unit 26 is comprised of, for example, a general-purpose or dedicated computer (see FIG. 6, which will be described later).

The communication section 261 is coupled to the network 7 and functions as a communication interface for transmitting and receiving various data. The input section 262 receives various input operations. The output section 263 functions as a user interface by outputting various information via a display screen, lighting of signal tower, or buzzer sound.

The memory section 264 stores therein various programs (operating system (OS), application programs, web browser, etc.) and data (the device setting information 265, the substrate recipe information 266, etc.) used in the operations of the substrate processing device 2. The device setting information 265 and the substrate recipe information 266 are data that can be edited by the user via the display screen.

The control section 260 obtains detection values of the multiple sensors 2181 to 218q, 2281 to 228s, 2381 to 238u, 2481 to 248w, 2581 to 258y (hereinafter referred to as “sensor group”) via multiple sequencers 219, 229, 239, 249, 259 (hereinafter referred to as “sequencer group”). The control section 260 operates the multiple modules 2171 to 217p, 2271 to 227r, 2371 to 237t, 2471 to 247v, and 2571 to 257x (hereinafter referred to as “module group”) in cooperation to perform a series of substrate processes including loading, polishing, cleaning, drying, film-thickness measuring, and unloading.

### Hardware Configuration of Each Device

FIG. 6 is a hardware configuration diagram showing an example of a computer 900. Each of the control unit 26, the database device 3, the machine-learning device 4, the information processing device 5, and the user terminal device 6 of the substrate processing device 2 is configured by the general-purpose or dedicated computer 900.

As shown in FIG. 6, main components of the computer 900 include buses 910, a processor 912, a memory 914, an input device 916, an output device 917, a display device 918, a storage device 920, a communication I/F (interface) section 922, an external device I/F section 924, an I/O (input/output) device I/F section 926, and a media input/output section 928. The above components may be omitted as appropriate depending on an application in which the computer 900 is used.

The processor 912 includes one or more arithmetic processing unit(s) (CPU (Central Processing Unit), MPU (Micro-processing unit), DSP (digital signal processor), GPU (Graphics Processing Unit), etc.), and operates as a controller configured to control the entire computer 900. The memory 914 stores various data and programs 930, and includes, for example, a volatile memory (DRAM, SRAM, etc.) that functions as a main memory, a non-volatile memory (ROM), a flash memory, etc.

The input device 916 includes, for example, a keyboard, a mouse, a numeric keypad, an electronic pen, etc., and functions as an input section. The output device 917 includes, for example, a sound (voice) output device, a vibration device, etc., and functions as an output section. The display device 918 includes, for example, a liquid crystal display, an organic EL display, electronic paper, a projector, etc., and functions as an output section. The input device 916 and the display device 918 may be configured integrally, such as a touch panel display. The storage device 920 includes, for example, HDD (Hard Disk Drive), SSD (Solid State Drive), etc., and functions as a storage section. The storage device 920 stores various data necessary for executing the operating system and the programs 930.

The communication I/F section 922 is coupled to a network 940, such as the Internet or an intranet (which may be the same as the network 7 in FIG. 1), in a wired manner or a wireless manner, and transmits and receives data to and from another computer according to a predetermined communication standard. The communication I/F section 922 functions as a communication unit that sends and receives information. The external device I/F section 924 is coupled to an external device 950, such as camera, printer, scanner, reader/writer, etc. in a wired manner or a wireless manner, and serves as a communication section that transmits and receives data to and from the external device 950 according to a predetermined communication standard. The I/O device I/F unit 926 is coupled to I/O devices 960, such as various sensors or actuators, and functions as a communication unit that transmits and receives various signals, such as detection signals from the sensors or control signals to the actuators, and data to and from the I/O devices 960. The media input/output unit 928 is constituted of a drive device, such as a DVD drive or a CD drive, and writes and reads data into and from medium (non-transitory storage medium) 970, such as a DVD or a CD.

In the computer 900 having the above configurations, the processor 912 calls the program 930 stored in the storage device 920 into the memory 914 and executes the program 930, and controls each part of the computer 900 via the buses 910. The program 930 may be stored in the memory 914 instead of the storage device 920. The program 930 may be stored in the medium 970 in an installable file format or an executable file format, and may be provided to the computer 900 via the media input/output unit 928. The program 930 may be provided to the computer 900 by being downloaded via the network 940 and the communication I/F unit 922. The computer 900 performs various functions realized by the processor 912 executing the programs 930. The computer 900 may include hardware, such an FPGA, an ASIC, etc. for executing the above-described various functions.

The computer 900 is, for example, a stationary computer or a portable computer, and is an electronic device in arbitrary form. The computer 900 may be a client computer, a server computer, or a cloud computer. The computer 900 may be applied to devices other than the devices 2 to 6.

### Production History Information 30

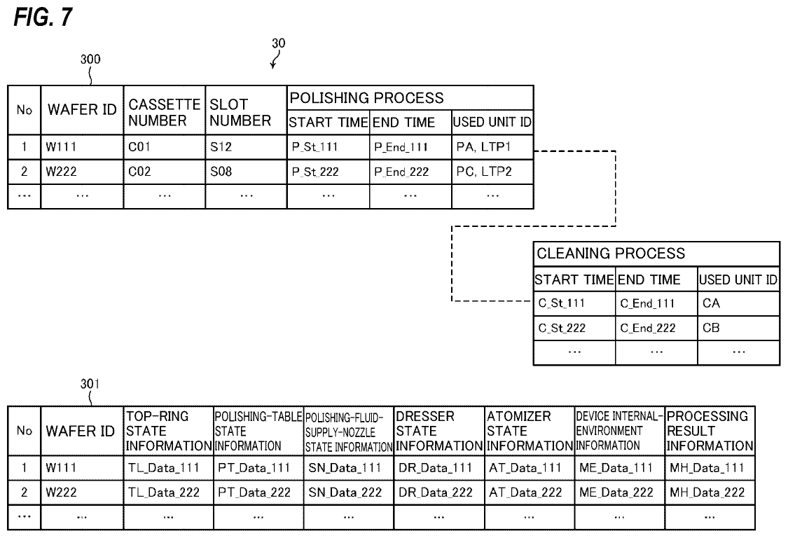

FIG. 7 is a data configuration diagram showing an example of the production history information 30 managed by the database device 3. The production history information 30 includes, for example, a wafer history table 300 with respect to each of the wafers W, and a polishing history table 301 with respect to the device-state information in the polishing process, as a table in which the reports R obtained in the substrate process using the polishing pad for proper production are classified and registered. The production history information 30 includes a cleaning history table with respect to the device-state information in the cleaning process, an event history table with respect to the event information, a manipulation history table with respect to the manipulation information, and the like, in addition to the above-described tables, but detailed descriptions thereof are omitted.

For example, a wafer ID, a cassette number, a slot number, start time and end time of each process, a used unit ID, etc. are registered in each record of the wafer history table 300. The polishing process and the cleaning process are illustrated as examples in FIG. 7. Data is registered in the other processes in the same manner.

For example, a wafer ID, top-ring state information, polishing-table state information, polishing-fluid-supply-nozzle state information, dresser state information, atomizer state information, device internal-environment information, processing result information, etc. are registered in each record of the polishing history table 301.

The top-ring state information is information indicating a state of the top ring 221 in the polishing process. The top-ring state information is, for example, detection values of each sensor (or command values to each module) sampled at predetermined time intervals by the sensor group (or the module group) of the top ring 221.

The polishing-table state information is information indicating a state of the polishing table 220 in the polishing process. The polishing-table state information is, for example, detection values of each sensor (or command values to each module) sampled at predetermined time intervals by the sensor group (or the module group) of the polishing table 220.

The polishing-fluid-supply-nozzle state information is information indicating a state of the polishing-fluid supply nozzle 222 in the polishing process. The polishing-fluid-supply-nozzle state information is, for example, detection values of each sensor (or command values to each module) sampled at predetermined time intervals by the sensor group (or the module group) of the polishing-fluid supply nozzle 222.

The dresser state information is information indicating a state of the dresser 223 in the polishing process. The dresser state information is, for example, detection values of each sensor (or command values to each module) sampled at predetermined time intervals by the sensor group (or the module group) of the dresser 223.

The atomizer state information is information indicating a state of the atomizer 224 in the polishing process. The atomizer state information is, for example, detection values of each sensor (or command values to each module) sampled at predetermined time intervals by the sensor group (or the module group) of the atomizer 224.

The device internal-environment information is information indicating a state of the internal space of the substrate processing device 2 formed by the housing 20. The internal space of the substrate processing device 2 is a space in which the polishing unit 22 is disposed. The device internal-environment information is, for example, detection values of each sensor sampled by the environment sensor 225 at predetermined time intervals. When the internal space of the substrate processing device 2 is separated for each of the first to fourth polishing sections 22A to 22D of the polishing unit 22, the environment sensor 225 is installed for each of the first to fourth polishing sections 22A to 22D, and the device internal-environment information is obtained for each of the first to fourth polishing sections 22A to 22D.

The processing result information is information indicating a result of the polishing process. The processing result information includes the cumulative number of wafers W or the cumulative use time that has been used or spent in the polishing process using the polishing pad 2200 since the polishing pad 2200 have been replaced.

By referring to the polishing history table 301, time-series data of each sensor (or time-series data of each module) can be extracted as a state of the substrate processing device 2 when the polishing process is performed on the wafer W identified by the wafer ID.

### Polishing-Test Information 31

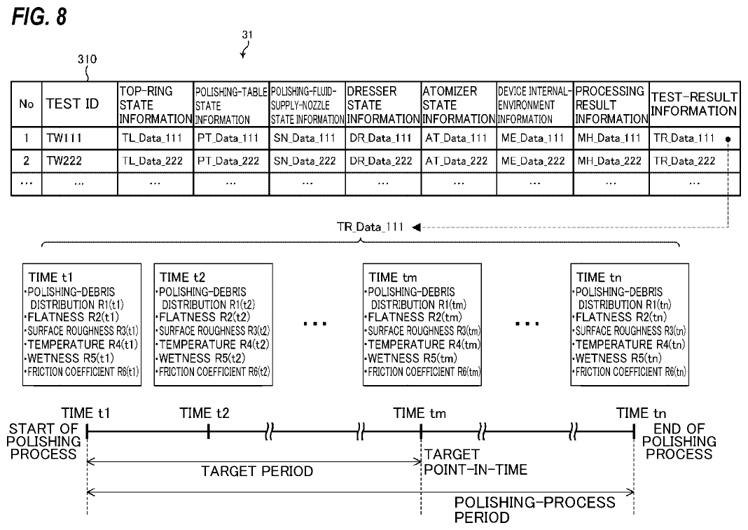

FIG. 8 is a data configuration diagram showing an example of the polishing-test information 31 managed by the database device 3. The polishing-test information 31 includes a polishing-test table 310 in which the reports R and the test results obtained in the polishing test performed using the polishing pad for test or the polishing-test device are classified and registered.

For example, a test ID, the top-ring state information, the polishing-table state information, the polishing-fluid-supply-nozzle state information, the dresser state information, the atomizer state information, the device internal-environment information, the processing result information, the test-result information etc. are registered in each record of the polishing-test table 310. The top-ring state information, the polishing-table state information, the polishing-fluid-supply-nozzle state information, the dresser state information, the atomizer state information, the device internal-environment information, and the processing result information of the polishing-test table 310 are information indicating states of the respective sections in the polishing test. Data configurations of these information are the same as those of the polishing history table 301, and detailed descriptions will be omitted.

The test-result information is information indicating a state of the polishing pad for test when the polishing process is performed in the polishing test. The test-result information is measurement values sampled at predetermined time intervals by the polishing-pad measuring device provided at the polishing pad for test or the polishing-test device. The test-result information shown in FIG. 8 includes measurement values V1 to V4 of the distribution state of the polishing debris, the flatness, the surface roughness, the temperature, the wetness, and the friction coefficient of the polishing surface at times t1, t2, . . . , . . . tm, . . . , tn within a polishing-process period from start to end of the polishing process. Examples of the polishing debris include shavings scraped off from the wafer W, shavings of consumable members (e.g., the polishing pad, the retainer ring, or the dresser disk), and residues of the polishing fluid. The test-result information may be the measurement values which are the measurement results obtained by the polishing-pad measuring device as described above. Alternatively, the camera installed as the environment sensor 225 or a camera mounted to an optical microscope or a scanning electron microscope (SEM) may generate images of the polishing pad for test at predetermined time intervals, and the test result information may be obtained based on a result of image processing performed on the images, or based on a result of experimental analysis performed on the images by an experimenter. Further, the test-result information may be collected in one polishing test which is performed consecutively from start to end of the polishing process, or may be collected in multiple polishing tests which are performed repeatedly from start of the polishing process until a predetermined time is reached, with the predetermined time gradually lengthened.

By referring to the polishing-test table 310, time-series data of each sensor (or time-series data of each module) indicating a state of the polishing unit 22 when the polishing process is performed using the polishing pad for test in the polishing test identified by the test ID, and time-series data of each sensor indicating the state of the polishing pad for test at that time can be extracted.

### Machine-Learning Device 4

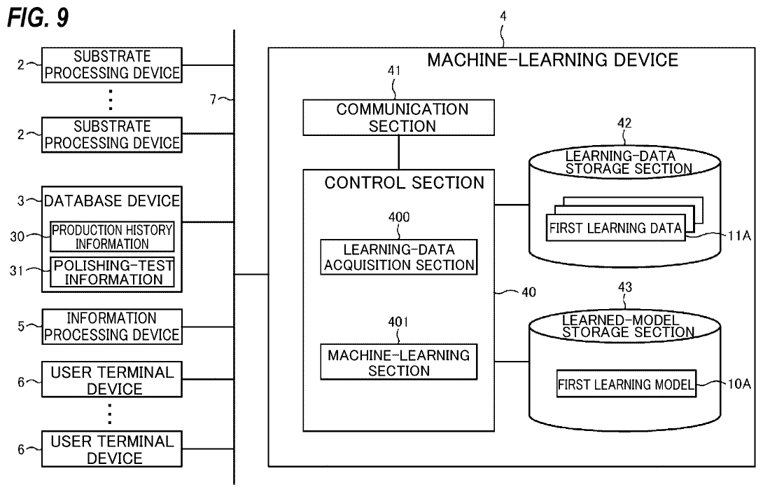

FIG. 9 is a block diagram showing an example of the machine-learning device 4 according to the first embodiment. The machine-learning device 4 includes a control section 40, a communication section 41, a learning-data storage section 42, and a learned-model storage section 43.

The control section 40 functions as a learning-data acquisition section 400 and a machine-learning section 401. The communication section 41 is coupled to external devices (e.g., the substrate processing device 2, the database device 3, the information processing device 5, the user terminal device 6, the polishing-test device (not shown), etc.) via the network 7. The communication section 41 serves as a communication interface configured to transmit and receive various data.

The learning-data acquisition section 400 is coupled to an external device via the communication section 41 and the network 7. The learning-data acquisition section 400 acquires the first learning data 11A including operating condition information as input data and the polishing-pad state information as output data. The first learning data 11A is data used as teacher data (or training data), verification data, and test data in supervised learning. The polishing-pad state information is used as ground-truth label or correct label in the supervised learning.

The learning-data storage section 42 is a database that stores multiple sets of first learning data 11A acquired by the learning-data acquisition section 400. The specific configuration of the database that constitutes the learning-data storage section 42 may be designed as appropriate.

The machine-learning section 401 performs the machine learning using the multiple sets of first learning data 11A stored in the learning-data storage section 42. Specifically, the machine-learning section 401 inputs the multiple sets of first learning data 11A to the first learning model 10A and causes the first learning model 10A to learn a correlation between the operating condition information and the polishing-pad state information included in the first learning data 11A to thereby create the first learning model 10A as a learned model.

The learned-model storage section 43 is a database configured to store the first learning model 10A as the learned model (i.e., adjusted weight parameter group) created by the machine-learning section 401. The first learning model 10A as the learned model stored in the learned-model storage section 43 is provided to a real system (e.g., the information processing device 5) via the network 7, a storage medium, or the like. Although the learning-data storage section 42 and the learned-model storage section 43 are shown as separate storage sections in FIG. 9, they may be configured as a single storage section.

The number of first learning model 10A stored in the learned-model storage section 43 is not limited to one. For example, a plurality of learning models may be stored in the learned-model storage section 43 for different conditions, such as for a difference in a machine-learning method, a type of the wafer W (a size, a thickness, a film type, etc.), a type of the polishing pad 2200, mechanism and material of the top ring 221, a type of the membrane 2212, a type of the retainer ring 2213, a type of the polishing fluid, a type of the dresser disk 2300, a type of the cleaning fluid, a type of data included in the operating condition information, a type of data included in the polishing-pad state information. In that case, a plurality of types of learning data having data configurations corresponding respectively to the plurality of learning models for the different conditions may be stored in the learning-data storage section 42.

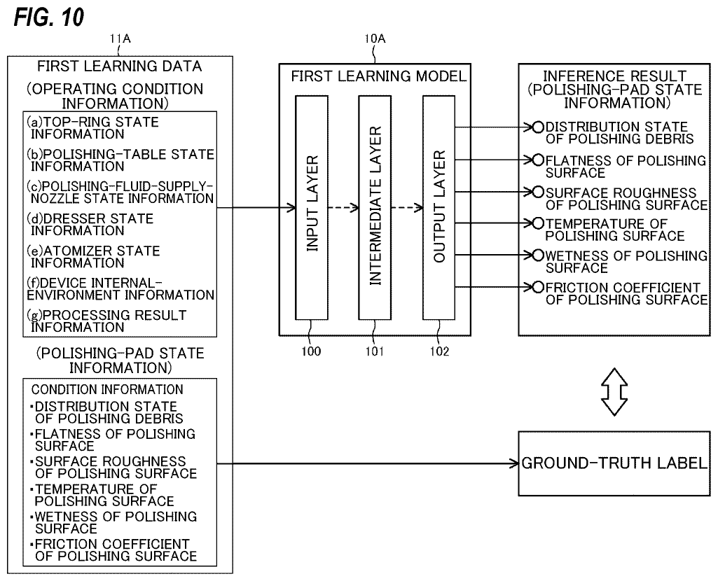

FIG. 10 is a diagram showing an example of the first learning model 10A and the first learning data 11A. The first learning data 11A used for the machine learning for the first learning model 10A includes the operating condition information and the polishing-pad state information.

The operating condition information constituting the first learning data 11A includes the top-ring state information indicating the state of the top ring 221 in the polishing process performed on the wafer W by the substrate processing device 2, the polishing-table state information indicating the state of the polishing table 220, the polishing-fluid-supply-nozzle state information indicating the state of the polishing-fluid supply nozzle 222, the dresser state information indicating the state of the dresser 223, and the atomizer state information indicating the state of the atomizer 224.

The top-ring state information included in the operating condition information includes at least one of the rotation speed of the top ring 221, the rotation torque of the top ring 221, the oscillation position of the top ring 221, the oscillation torque of the top ring 221, the height of the top ring 221, and the elevating torque of the top ring 221, the pressures (membrane pressures) in the membrane pressure chambers 2212a to 2212d, the flow rates (membrane flow-rates) of the pressurized fluid supplied to the membrane pressure chambers 2212a to 2212d, a condition of the membrane 2212, the pressure (retainer-ring airbag pressure) in the retainer-ring pressure chamber 2214a, the flow rate (retainer-ring airbag flow-rate) of the pressurized fluid supplied to the retainer-ring pressure chamber 2214a, and a condition of the retainer ring 2213. The condition of the membrane 2212 is represented by, for example, a surface property, an expansion and contraction state, a thickness, etc., and is set based on a use state of the membrane 2212 (e.g., use time, replaced or not replaced), the top-ring state information, the polishing-table state information, etc. The condition of the retainer ring 2213 is represented by, for example, a surface property, a flatness, a thickness, a cross-sectional shape, scraping or contamination of an inner periphery, and is set based on a use state of the retainer ring 2213 (e.g., use time, replaced or not replaced), the top-ring state information, the polishing-table state information, etc. For example, the conditions of the membrane 2212 and the retainer ring 2213 may change over time during the polishing process.

The polishing-table state information included in the operating condition information includes at least one of the rotation speed of the polishing table 220, the rotation torque of the polishing table 220, the surface temperature of the polishing pad 2200, and a condition of the polishing pad 2200. The condition of the polishing pad 2200 indicates a condition of the polishing pad 2200 at a point in time before a target point-in-time in the polishing-pad state information. The condition of the polishing pad 2200 is represented by, for example, a surface property, a flatness, a cleanliness, a temperature, a wetness, a friction coefficient etc., and is set based on a use state of the polishing pad 2200 (e.g., use time, a membrane pressure or a retainer-ring airbag pressure during use, dressed or not dressed, replaced or not replaced, an image of the surface of the polishing pad 2200), the top-ring state information, the polishing-table state information, the polishing-fluid-supply-nozzle state information, the dresser state information, the atomizer state information, etc. For example, the condition of the polishing pad 2200 may change over time during the polishing process.

The polishing-fluid-supply-nozzle state information included in the operating condition information includes at least one of the flow rate of the polishing fluid, the dropping position of the polishing fluid, and the temperature of the polishing fluid. When the polishing fluid is a plurality of types of polishing fluid (e.g., a polishing liquid, pure water, chemical liquid, dispersant, etc.), the polishing-fluid-supply-nozzle state information may include at least one of flow rates for the respective types, dropping positions for the respective types, and temperatures for the respective types. For example, when the polishing fluid is a polishing liquid and pure water, the polishing-fluid-supply-nozzle state information may include at least one of a flow rate of the polishing liquid, a dropping position of the polishing liquid, a temperature of the polishing liquid, a flow rate of the pure water, a dropping position of the pure water, and a temperature of the pure water.

The dresser state information included in the operating condition information includes at least one of the rotation speed of the dresser 223, the rotation torque of the dresser 223, the oscillation position of the dresser 223, the oscillation speed of the dresser 223, the oscillation torque of the dresser 223, the height of the dresser 223, the pressing load when the dresser disk 2230 is brought into contact with the polishing pad 2230, and a condition of the dresser disk 2230. The condition of the dresser disk 2230 is represented by, for example, a degree of wear of the dresser disk 2230 set based on a use state of the dresser disk 2230 (e.g., use time, a pressing load during use, replaced or not replaced, and an image of a surface of the dresser disk 2230). For example, the condition of the dresser disk 2230 may change over time during the polishing process.

The atomizer state information included in the operating condition information includes at least one of the flow rate of the cleaning fluid, the dropping position of the cleaning fluid, and the pressure of the cleaning fluid.

The operating condition information may further include the device internal-environment information indicating the environment of the space in which the polishing process is performed. The device internal-environment information included in the operating condition information includes at least one of the temperature, the humidity, the atmospheric pressure, the airflow, the oxygen concentration, and the sound of the internal space formed by the housing 20 (for each of the first to fourth polishing sections 22A to 22D). The operating condition information may further include the processing result information indicating a result of the polishing process. For example, the processing result information included in the operating condition information may include at least one of the cumulative number of wafers W, and the cumulative use time that has been used or spent in the polishing process using the polishing pad 2200 since the polishing pad 2200 have been replaced.

The polishing-pad state information constituting the first learning data 11A is information indicating the state of the polishing pad 2200 when the substrate processing device 2 operates under the operating conditions indicated by the operating condition information. In this embodiment, the polishing-pad state information is condition information indicating a condition of the polishing surface of the polishing pad 2200. The condition information includes, for example, at least one of the distribution state of the polishing debris, the flatness, the surface roughness, the temperature, the wetness, and the friction coefficient of the polishing surface at a target point-in-time included in the polishing-process period from start to end of the polishing process (i.e., time required for polishing per wafer). The polishing-process period includes an operation in which the top ring 221 presses the wafer W against the polishing pad 2200, an operation in which the polishing-fluid supply nozzle 222 supplies the polishing fluid to the polishing pad 2200, an operation in which the dresser 223 brings the dresser disk 2230 into contact with the polishing pad 2200 to dress the polishing pad 2200, and an operation in which the atomizer 224 emits the cleaning fluid to the polishing pad 2200.

The learning-data acquisition section 400 acquires the first learning data 11A by referring to the polishing-test information 31 and receiving, as necessary, the input manipulations of the user through the user terminal device 6. For example, the learning-data acquisition section 400 refers to the polishing-test table 310 of the polishing-test information 31, thereby acquiring, as the operating condition information, the top-ring state information, the polishing-table state information, the polishing-fluid-supply-nozzle state information, the dresser state information, and the atomizer state information (time-series data of sensors of the top ring 221, the polishing table 220, the polishing-fluid supply nozzle 222, the dresser 223, and the atomizer 224) when the polishing test identified by the test ID is performed.

In this embodiment, a case will be described where the operating condition information is acquired as the time-series data of the sensor group as shown in FIG. 10. The operating condition information may be changed as appropriate according to constructions of the polishing unit 22 (particularly the top ring 21, the polishing table 220, the polishing-fluid supply nozzle 222, the dresser 223, and the atomizer 224). In addition, a command value to the module, a parameter converted from a detected value of the sensor or the command value to the module, or a parameter calculated based on detected values of a plurality of sensors may be used as the operating condition information. Furthermore, the operating condition information may be acquired as time-series data in the entire polishing-process period, may be acquired as time-series data in the target period that is part of the polishing-process period, or may be acquired as point-in-time data at a specific target point-in-time. When the definition of the operating condition information is changed as described above, the data structure of the input data in the first learning model 10A and the first learning data 11A may be changed as appropriate.

The learning-data acquisition section 400 refers to the polishing-test table 310 of the polishing-test information 31, thereby acquiring, as the polishing-pad state information for the operating condition information, the test-result information (e.g., the time-series data (see FIG. 8) of the polishing-pad measuring device) when the polishing test identified by the same test ID is performed. When the polishing-pad measuring device is configured to be able to perform planarly measuring operation on the polishing surface of the polishing pad 2200, the learning-data acquisition section 400 acquires an in-plane measurement value for the polishing surface as the polishing-pad state information.

In this embodiment, a case will be described where the polishing-pad state information is the condition information as shown in FIG. 10, but the polishing-pad state information may include at least one of the distribution state of the polishing debris, the flatness, the surface roughness, the temperature, the wetness, and the friction coefficient of the polishing surface. The polishing-pad state information may be calculated by substituting the measurement value of the polishing-pad measuring device into a predetermined calculation formula. Further, when the operating condition information is acquired as the time-series data in the entire polishing-process period or the time-series data in the target period that is part of the polishing-process period, the polishing-pad state information may be acquired as time-series data in the entire polishing-process period or time-series data in the target period, or may be acquired as point-in-time data at the end of polishing of the wafer W or point-in-time data at the target point-in-time. When the operating condition information is acquired as, for example, the point-in-time data at the specific target point-in-time, the polishing-pad state information may be acquired as point-in-time data at the specific target point-in-time. When the definition of the polishing-pad state information is changed as described above, the data structure of the output data in the first learning model 10A and the first learning data 11A may be changed as appropriate.

The first learning model 10A employs, for example, a neural network structure, and includes an input layer 100, an intermediate layer 101, and an output layer 102. Synapses (not shown) connecting neurons are placed between the layers, and each synapse is associated with a weight. A weight parameter group including weights of the synapses is adjusted by the machine learning.

The input layer 100 has neurons corresponding to the operating condition information as the input data, and each value of the operating condition information is input to each neuron. The output layer 102 has neuron(s) corresponding to the polishing-pad state information as the output data, and a prediction result (inference result) of the polishing-pad state information for the operating condition information is output as the output data. When the first learning model 10A is constituted of a regression model, the polishing-pad state information is output as a numerical value normalized to a predetermined range (e.g., 0 to 1). When the first learning model 12A is constituted of a classification model, the polishing-pad state information is output as a numerical value normalized to a predetermined range (e.g., 0 to 1) as a score (confidence) for each class.

### Machine-Learning Method

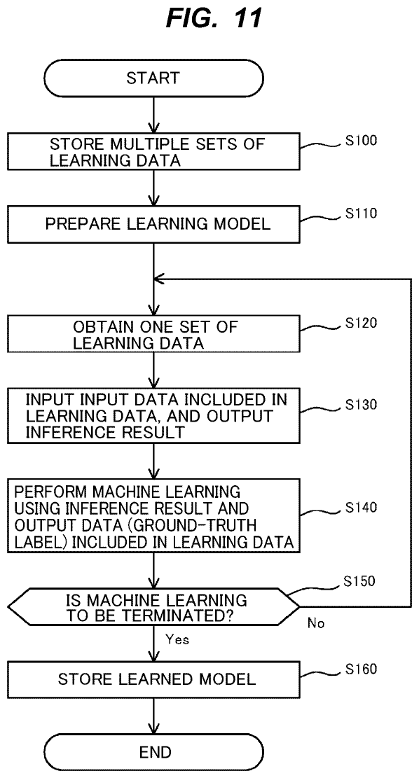

FIG. 11 is a flowchart illustrating an example of a machine-learning method performed by the machine-learning device 4.

First, in step S100, the learning-data acquisition section 400 obtains, from the polishing-test information 31 or the like, a desired number of first learning data 11A as advance preparation for starting the machine learning, and stores the obtained first learning data 11A in the learning-data storage section 42. The number of first learning data 11A to be prepared may be set in consideration of the inference accuracy required for the first learning model 10A finally obtained.

Next, in step S110, the machine-learning section 401 prepares the first learning model 10A before learning for starting the machine learning. The first learning model 10A prepared before learning in this embodiment is composed of the neural network model illustrated in FIG. 10, and the weight of each synapse is set to an initial value.

Next, in step S120, the machine-learning section 401 randomly obtains, for example, one set of first learning data 11A from the multiple sets of first learning data 11A stored in the learning-data storage section 42.

Next, in step S130, the machine-learning section 401 inputs the operating condition information (input data) included in the one set of first learning data 11A to the input layer 100 of the prepared first learning model 10A before learning (or during learning). As a result, the polishing-pad state information (the output data) is output as the inference result from the output layer 102 of the first learning model 10A. However, the output data is generated by the first learning model 10A before learning (or during learning). Therefore, in the state before learning (or during learning), the output data output as the inference result may indicate different information from the polishing-pad state information (ground-truth label) included in the first learning data 11A.

Next, in step S140, the machine-learning section 401 performs the machine learning by comparing the polishing-pad state information (ground-truth label) included in the one set of first learning data 11A acquired in the step S120 with the polishing-pad state information (output data) output as the inference result from the output layer in the step S130, and adjusting the weight of each synapse (backpropagation). In this way, the machine-learning section 401 causes the first learning model 10A to learn a correlation between the operating condition information and the polishing-pad state information.

Next, in step S150, the machine-learning section 401 determines whether a predetermined learning end condition is satisfied. For example, this determination is made based on an evaluation value of an error function based on the polishing-pad state information (ground-truth label) included in the first learning data 11A and the polishing-pad state information (output data) output as the inference result, or the remaining number of unlearned first learning data 11A stored in the learning-data storage section 42.

In the step S150, if the machine-learning section 401 has determined that the learning end condition is not satisfied and the machine learning is to be continued (“No” in the step S150), the process returns to the step S120, and the steps S120 to S140 are performed on the first learning model 10A multiple times using the unlearned first learning data 11A. On the other hand, if the machine-learning section 401 has determined that the learning end condition is satisfied and the machine learning is to be terminated (“Yes” in the step S150) in the step S150, the process proceeds to step S160.

Then, in the step S160, the machine-learning section 401 stores, in the learned-model storage section 43, the first learning model 10A as the learned model (adjusted weight parameter group) created by adjusting the weight associated with each synapse. The sequence of machine-learning processes shown in FIG. 11 is completed. In the machine-learning method, the step S100 corresponds to a learning-data storing process, the steps S110 to S150 correspond to a machine-learning process, and the step S160 corresponds to a learned-model storing process.

As described above, the machine-learning device 4 and the machine-learning method according to the present embodiment can provide the first learning model 10A capable of predicting (inferring) the polishing-pad state information indicating the state of the polishing pad 2200 from the operating condition information including the top-ring state information, the polishing-table state information, the polishing-fluid-supply-nozzle state information, the dresser state information, and the atomizer state information.

### Information Processing Device 5

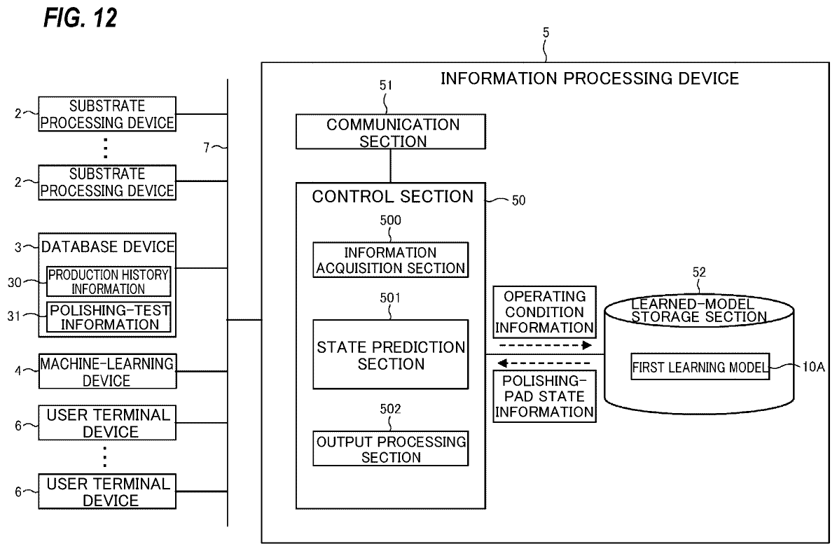

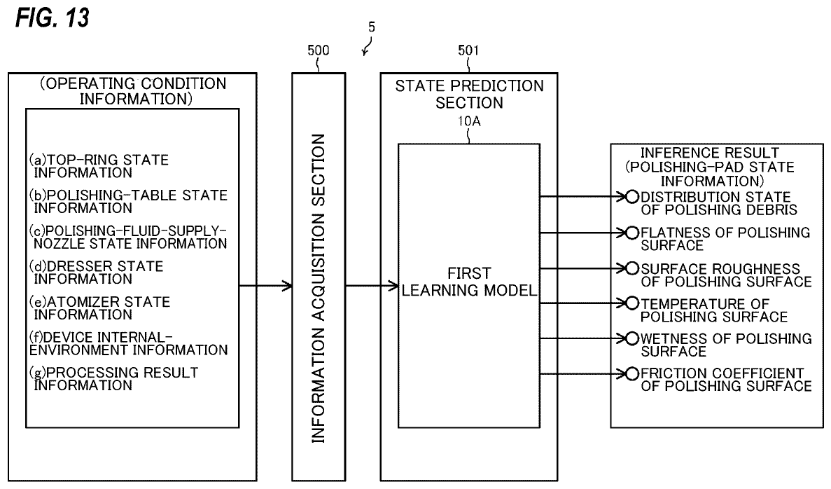

FIG. 12 is a block diagram showing an example of the information processing device 5 according to the first embodiment. FIG. 13 is a functional explanatory diagram showing an example of the information processing device 5 according to the first embodiment. The information processing device 5 includes a control section 50, a communication section 51, and a learned-model storage section 52.

The control section 50 functions as an information acquisition section 500, a state prediction section 501, and an output processing section 502. The communication section 51 is coupled to the external devices (e.g., the substrate processing device 2, the database device 3, the machine-learning device 4, the user terminal device 6, etc.) via the network 7, and serves as a communication interface configured to transmit and receive various data.

The information acquisition section 500 is coupled to an external device via the communication section 51 and the network 7 and acquires the operating condition information including the top-ring state information, the polishing-table state information, the polishing-fluid-supply-nozzle state information, the dresser state information, and the atomizer state information.

For example, when the “post-predicting process” of the polishing-pad state information is performed for the wafer W on which the polishing process has already been performed, the information acquisition section 500 refers to the polishing history table 301 of the production history information 30, thereby acquiring the top-ring state information, the polishing-table state information, the polishing-fluid-supply-nozzle state information, the dresser state information, and the atomizer state information as the operating condition information when the polishing process is performed on the wafer W. When the “real-time-predicting process” of the polishing-pad state information is performed for the wafer W during polishing, the information acquisition section 500 receives the report R on the device-state information from the substrate processing device 2 performing the polishing of the wafer W, thereby acquiring, as the operating condition information, the top-ring state information, the polishing-table state information, the polishing-fluid-supply-nozzle state information, the dresser state information, and the atomizer state information during the polishing process. When the “pre-predicting process” of the polishing-pad state information is performed for the wafer W before the polishing process, the information acquisition section 500 receives the substrate recipe information 266 from the substrate processing device 2 that is to perform the polishing of the wafer W and simulates the device-state information when the polishing unit 22 operates according to the substrate recipe conditions 266, thereby acquiring, as the operating condition information, the top-ring state information, the polishing-table state information, the polishing-fluid-supply-nozzle state information, the dresser state information, and the atomizer state information when the polishing process is to be performed on the wafer W.

As described above, the state prediction section 501 inputs the operating condition information acquired by the information acquisition section 500 as the input data to the first learning model 10A, thereby predicting the polishing-pad state information (in this embodiment, the condition information) indicating the state of the polishing pad when the substrate processing device 2 operates under the operating conditions indicated by the operating condition information.

The learned-model storage section 52 is a database configured to store the first learning model 10A as the learned model for use in the state prediction section 501. The number of first learning model 10A stored in the learned-model storage section 52 is not limited to one. For example, a plurality of learned models 10A may be stored in the learned-model storage section 52 for different conditions, such as for a difference in a machine-learning method, a type of the wafer W (e.g., a size, a thickness, a film type, etc.), a type of the polishing pad 2200, mechanism and material of the top ring 221, a type of the membrane 2212, a type of the retainer ring 2213, a type of the polishing fluid, a type of the dresser disk 2300, a type of the cleaning fluid, a type of data included in the operating condition information, and a type of data included in the polishing-pad state information. The plurality of learned models 10A may be selectively used. The learned-model storage section 52 may be a storage section of an external computer (e.g., a server type computer or a cloud type computer). In that case, the state prediction section 501 accesses the external computer.

The output processing section 502 performs output processing to output the polishing-pad state information generated by the state prediction section 501. For example, the output processing section 502 may transmit the polishing-pad state information to the substrate processing device 2 or the user terminal device 6, so that a display screen based on the polishing-pad state information may be displayed on the substrate processing device 2 or the user terminal device 6. The output processing section 502 may transmit the polishing-pad state information to the database device 3, so that the polishing-pad state information may be registered in the production history information 30.

### Information Processing Method

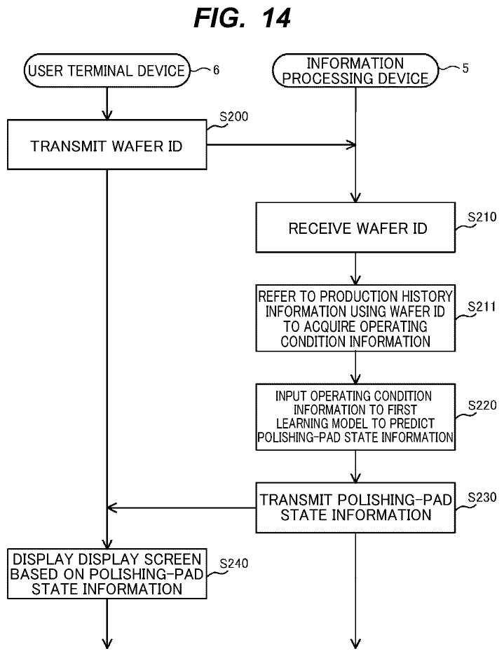

FIG. 14 is a flowchart illustrating an example of an information processing method performed by the information processing device 5. In this embodiment, an operation example will be described in a case where the user manipulates the user terminal device 6 to perform the “post-predicting process” of the polishing-pad state information for a specific wafer W.

First, in step S200, when the user performs an input operation of inputting a wafer ID for identifying a wafer W to be predicted on the user terminal device 6, the user terminal device 6 transmits the wafer ID to the information processing device 5.

Next, in step S210, the information acquisition section 500 of the information processing device 5 receives the wafer ID transmitted in the step S200. In step S211, the information acquisition section 500 uses the wafer ID received in the step S210 to refer to the polishing history table 301 of the production history information 30, thereby acquiring the operating condition information when the polishing process is performed on the wafer W identified by the wafer ID.

Next, in step S220, the state prediction section 501 inputs the operating condition information acquired in the step S211 as input data to the first learning model 10A, thereby generating, as output data, the polishing-pad state information for the operating condition information and predicts a state of the polishing pad 2200.

Next, in step S230, the output processing section 502 transmits the polishing-pad state information to the user terminal device 6 as an output process for outputting the polishing-pad state information generated in the step S220. The polishing-pad state information may be transmitted to the database device 3 in addition to or instead of the user terminal device 6.

Next, in step S240, upon receiving the polishing-pad state information transmitted in the step S230, the user terminal device 6 displays a display screen based on the polishing-pad state information as a response to the transmission process in the step S200. As a result, the state of the polishing pad 2200 can be visually recognized by the user. In the above information processing method, the steps S210 and S211 correspond to an information acquisition process, the step S220 corresponds to a state prediction process, and the step S230 corresponds to an output processing process.

As described above, the information processing device 5 and the information processing method according to the present embodiment inputs the operating condition information including the top-ring state information, the polishing-table state information, the polishing-fluid-supply-nozzle state information, the dresser state information, and the atomizer state information in the polishing process to the first learning model 10A, so that the polishing-pad state information (condition information) for the operating condition information can be predicted. Therefore, the state of the polishing pad 2200 can be predicted appropriately according to the operating conditions of the substrate processing device 2.

### Second Embodiment

A second embodiment differs from the first embodiment in that the polishing-pad state information represents at least one of remaining service life information indicating a remaining service life of the polishing pad 2200, and polishing quality information indicating a polishing quality of the polishing pad 2200. In this embodiment, a machine-learning device 4a and an information processing device 5a according to the second embodiment will be described, focusing on differences from the first embodiment.

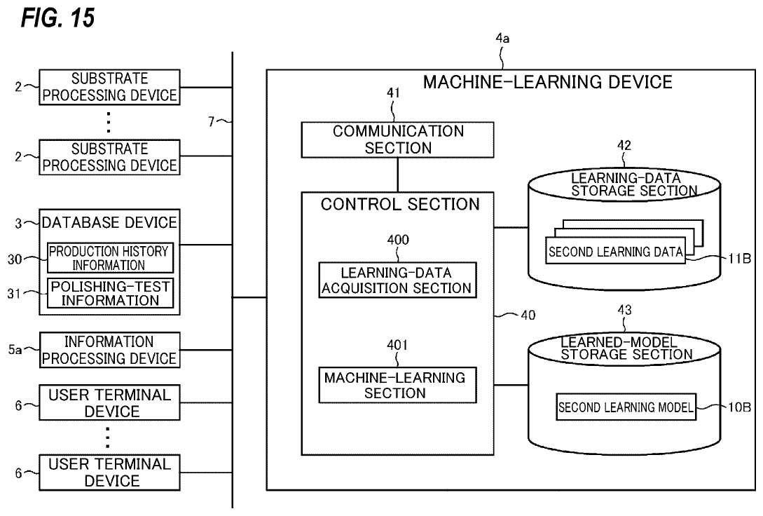

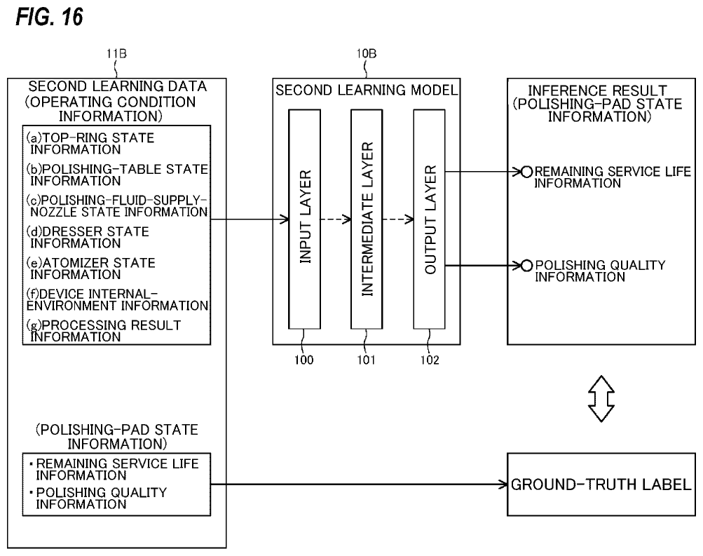

FIG. 15 is a block diagram showing an example of the machine-learning device 4a according to the second embodiment. FIG. 16 is a diagram showing an example of a second learning model 10B and second learning data 11B. The second learning data 11B is used for machine learning for the second learning model 10B.

The polishing-pad state information constituting the second learning data 11B is at least one of the remaining service life information indicating the remaining service life of the polishing pad 2200, and the polishing quality information indicating the polishing quality of the polishing pad 2200. The remaining service life of the polishing pad 2200 is determined, for example, by the number of times that the polishing pad 2200 can be used until the polishing pad 2200 reaches the end of its lifetime, and the usable time. The polishing quality of the polishing pad 2200 is determined, for example, by polishing degree information on a degree of polishing of the wafer W, such as a polishing rate, a polishing profile, and a remaining film, substrate defect information on a degree and presence or absence of defect of the wafer W, such as scratch or corrosion, etc. The operating condition information constituting the second learning data 11B is the same as that in the first embodiment, and descriptions will be omitted.

The learning-data acquisition section 400 acquires the second learning data 11B by referring to the polishing-test information 31 and receiving, as necessary, the input manipulations of the user through the user terminal device 6. Example of the polishing-test information 31 is as follows. When the polishing process is repeatedly performed using the polishing pad for test or the polishing-test device, the remaining service life information at a point when the service life of the polishing pad 2200 has been reached is set to “0” as the test-result information. A value representing the registered remaining service life information increases as the time goes back to the past. The polishing quality information measured by a measuring device, such as an optical microscope or a scanning electron microscope (SEM), is also registered as the test-result information in the polishing-test information 31. The learning-data acquisition section 400 acquires the remaining service life information and the polishing quality information by acquiring the test result information of the polishing test specified by the test ID from the polishing-test table 310 of the polishing-test information 31.

The machine-learning section 401 inputs multiple sets of second learning data 11B to the second learning model 10B, and causes the second learning model 10B to learn a correlation between the operating condition information and the polishing-pad state information (at least one of the remaining service life information and the polishing quality information) included in the second learning data 11B, thereby creating the second learning model 10B as a learned model.

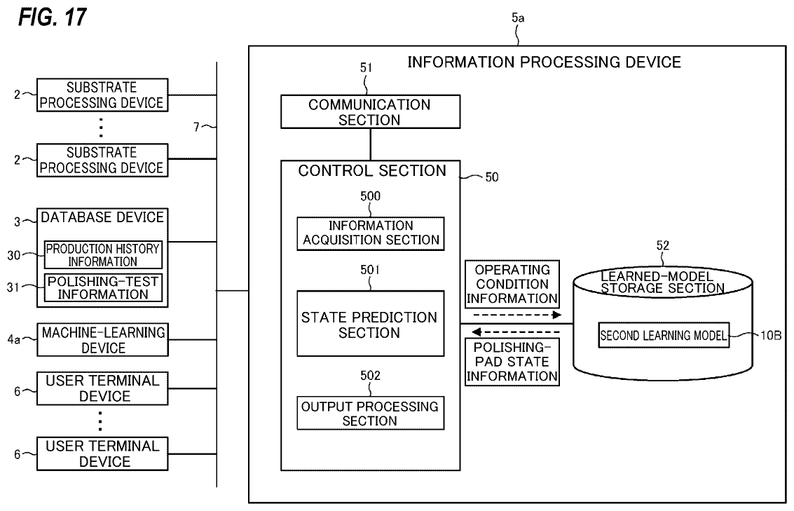

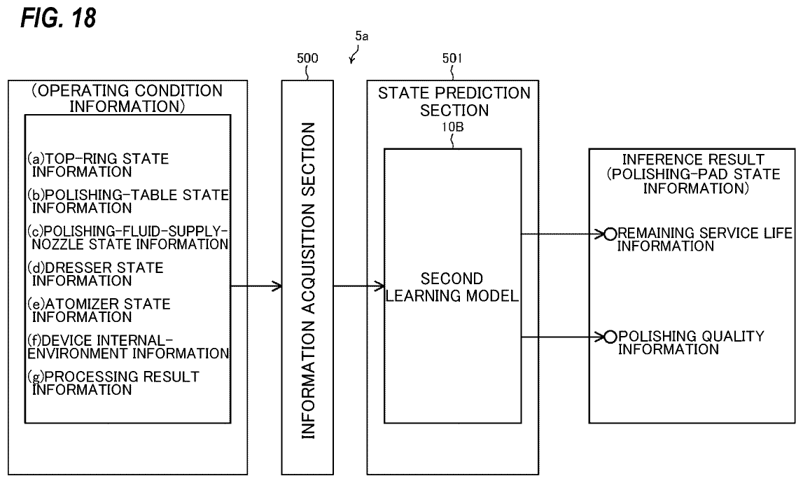

FIG. 17 is a block diagram showing an example of an information processing device 5a functioning as the information processing device 5a according to the second embodiment. FIG. 18 is a functional explanatory diagram showing an example of the information processing device 5a according to the second embodiment.

The information acquisition section 500 acquires the operating condition information including the top-ring state information, the polishing-table state information, the polishing-fluid-supply-nozzle state information, the dresser state information, and the atomizer state information as well as the first embodiment.

As described above, the state prediction section 501 inputs the operating condition information acquired by the information acquisition section 500 as the input data to the second learning model 10B, thereby predicting the polishing-pad state information (at least one of the remaining service life information and the polishing quality information) indicating the state of the polishing pad when the substrate processing device 2 operates under the operating conditions indicated by the operating condition information.

The output processing section 502 performs output processing to output the polishing-pad state information (at least one of the remaining service life information and the polishing quality information) generated by the state prediction section 501 as well as the first embodiment. For example, the output processing section 502 may transmit the polishing-pad state information to the substrate processing device 2 or the user terminal device 6, so that a display screen based on the polishing-pad state information may be displayed on the substrate processing device 2 or the user terminal device 6. The output processing section 502 may transmit the polishing-pad state information to the database device 3, so that the polishing-pad state information may be registered in the production history information 30. At this time, the output processing section 502 may transmit information for displaying a replacement previous-notice of the polishing pad 2200, a procedure manual for a replacing operation, a time required for the replacing operation, a price of a replacement part, etc. to the substrate processing device 2 or the user terminal device 6, for example, when the remaining service life of the polishing pad 2200 indicated by the remaining service life information is below a predetermined reference number for the previous notice or a predetermined reference time for the previous notice, or when the polishing quality indicated by the polishing quality information is below a predetermined reference quality. When the substrate processing device 2 has a function of automatically replacing the polishing pad 2200, the output processing section 502 may transmit an instruction to automatically replace the polishing pad 2200 to the substrate processing device 2, or may transmit an instruction to order the replacement part for the polishing pad 2200 to an inventory management device (not shown) configured to manage an inventory of the polishing pad 2200.

As described above, the information processing device 5a and the information processing method according to the present embodiment input the operating condition information including the top-ring state information, the polishing-table state information, the polishing-fluid-supply-nozzle state information, the dresser state information, and the atomizer state information in the polishing process to the second learning model 10B, so that the polishing-pad state information (at least one of the remaining service life information and the polishing quality information) for the operating condition information can be predicted. Therefore, the state of the polishing pad 2200 can be predicted appropriately according to the operating conditions of the substrate processing apparatus 2.

### Other Embodiments

The present invention is not limited to the above-described embodiments, and various modifications can be made and used without deviating from the scope of the present invention. All of them are included in the technical concept of the present invention.

In the above-described embodiments, the database device 3, the machine-learning device 4, and the information processing device 5 are described as being configured as separate devices, but these three devices may be configured as a single device. In one embodiment, any two of these three devices may be configured as a single device. Further, at least one of the machine-learning device 4 and the information processing device 5 may be incorporated into the control unit 26 of the substrate processing device 2 or the user terminal device 6.

In the above-described embodiments, the substrate processing device 2 is described as including the units 21 to 25, but the substrate processing device 2 may include at least the polishing unit 22, and the other units may be omitted.

In the embodiments described above, the neural network is employed as the learning model that implements the machine learning performed by the machine-learning section 401, while any other machine-learning model may be employed. Examples of the other machine-learning model include tree type (e.g., decision tree, regression tree), ensemble learning (e.g., bagging, boosting), neural network type including deep learning (e.g., recurrent neural network, convolutional neural network, LSTM), clustering type (e.g., hierarchical clustering, non-hierarchical clustering, k-nearest neighbor algorithm, k-means clustering), multivariate analysis (e.g., principal component analysis, factor analysis, logistic regression), and support vector machine.

### Machine Learning Program and Information Processing Program

The present invention can be provided in a form of a program (machine learning program) that causes the computer 900 to function as each section of the machine-learning devices 4, and in a form of a program (machine learning program) that causes the computer 900 to execute each process of the machine-learning method. Further, the present invention can be provided in a form of a program (information processing program) that causes the computer 900 to function as each section included in the information processing devices 5, and in a form of a program (information processing program) that causes the computer 900 to execute each process of the information processing method according to the above-described embodiments.

### Inference Apparatus, Inference Method, and Inference Program

The present invention can be provided not only in a form of the information processing device 5 (information processing method or information processing program) according to the above-described embodiments, but also in a form of an inference apparatus (inference method or information processing program) used for inferring the polishing-pad state information. In that case, the inference apparatus (inference method or inference program) may include a memory and a processor. The processor may execute a series of processes. The series of processes includes an information acquisition processing (information acquisition process) of acquiring the operating condition information, and an inference processing (inference process) of inferring the polishing-pad state information (the condition information, the remaining service life information, or the polishing quality information) indicating the state of the polishing pad when the substrate processing device 2 operates under the operating conditions indicated by the operating condition information when the operating condition information is acquired in the information acquisition processing.

The form of the inference apparatus (inference method or inference program) can be applied to various devices more easily than when the information processing device is implemented. It is readily understood by a person skilled in the art that the state prediction section may be applied with use of the learning model as the learned model created by the machine-learning device and the machine-learning method according to the above-described embodiments when the inference apparatus (inference method or inference program) infers the polishing-pad state information.

### INDUSTRIAL APPLICABILITY

The present invention is applicable to an information processing apparatus, an inference apparatus, a machine-learning device, an information processing method, an inference method, and a machine-learning method.

### REFERENCE SIGNS LIST

1 . . . substrate processing system, 2 . . . substrate processing device, 3 . . . database device,

4, 4a . . . machine-learning device, 5, 5a . . . information processing device,

6 . . . user terminal device, 7 . . . network,

10A . . . first learning model, 10B . . . second learning model,

11A . . . first learning data, 11B . . . second learning data,

20 . . . housing, 21 . . . load-unload unit,

22 . . . polishing unit, 22A to 22D . . . polishing section, 23 . . . substrate transport unit,

24 . . . finishing unit, 25 . . . film-thickness measuring unit, 26 . . . control unit,

30 . . . production history information, 31 . . . polishing-test information,

40 . . . control section, 41 . . . communication section, 42 . . . learning-data storage section,

43 . . . learned-model storage section,

50 . . . control section, 51 . . . communication section, 52 . . . learned-model storage section,

220 . . . polishing table, 221 . . . top ring, 222 . . . polishing-fluid supply nozzle,

223 . . . dresser, 224 . . . atomizer, 225 . . . environment sensor,

260 . . . control section, 21 . . . communication section, 262 . . . input section, 263 . . . output section,

264 . . . memory section,

300 . . . wafer history table, 301 . . . polishing history table, 310 . . . polishing-test table,

400 . . . learning-data acquisition section, 401 . . . machine-learning section,

500 . . . information acquisition section, 501 . . . state prediction section,

502 . . . output processing section, 900 . . . computer

2200 . . . polishing pad, 2210 . . . top ring body, 2211 . . . carrier,

2212 . . . membrane, 2212a to 2212d . . . membrane pressure chamber,

2213 . . . retainer ring, 2214 . . . retainer-ring airbag,

2214a . . . retainer-ring pressure chamber, 2230 . . . dresser disk

1. An information processing apparatus comprising:
an information acquisition section configured to acquire operating condition information as operating conditions under which a substrate processing apparatus operates, the operating condition information including top-ring state information indicating a state of a top ring, polishing-table state information indicating a state of a polishing table, polishing-fluid-supply-nozzle state information indicating a state of a polishing-fluid supply nozzle, dresser state information indicating a state of a dresser, and atomizer state information indicating a state of an atomizer, the substrate processing apparatus being configured to perform chemical mechanical polishing of a substrate and including the polishing table configured to rotatably support a polishing pad, the top ring configured to press the substrate against the polishing pad, the polishing-fluid supply nozzle configured to supply a polishing fluid onto the polishing pad, the dresser configured to rotatably support a dresser disk and bring the dresser disk into contact with the polishing pad to dress the polishing pad, and the atomizer configured to emit a cleaning fluid to the polishing pad; and
a state prediction section configured to predict polishing-pad state information for the operating condition information by inputting the operating condition information acquired by the information acquisition section to a learning model that has been generated by machine learning that causes the learning model to learn a correlation between the operating condition information and the polishing-pad state information indicating a state of the polishing pad when the substrate processing apparatus operates under the operating conditions indicated by the operating condition information.

2. The information processing apparatus according to claim 1, wherein the top ring includes:
a top ring body configured to be moved by a rotating mechanism, a vertical movement mechanism, and an oscillation mechanism;
a membrane housed in the top ring body and configured to press the substrate against the polishing pad according to pressurized fluid supplied to a membrane pressure chamber; and
a retainer ring disposed at a periphery of the membrane and configured to press the polishing pad according to pressurized fluid supplied to a retainer-ring pressure chamber, and
the top-ring state information included in the operating condition information includes at least one of:
a rotation speed of the top ring;
a rotation torque of the top ring;
an oscillation position of the top ring;
an oscillation speed of the top ring;
an oscillation torque of the top ring;
a height of the top ring;
an elevating torque of the top ring;
a pressure in the membrane pressure chamber;
a flow rate of the pressurized fluid supplied to the membrane pressure chamber;
a condition of the membrane;
a pressure in the retainer-ring pressure chamber;
a flow rate of the pressurized fluid supplied to the retainer-ring pressure chamber; and
a condition of the retainer ring.

3. The information processing apparatus according to claim 1, wherein the polishing-table state information included in the operating condition information includes at least one of:
a rotation speed of the polishing table;
a rotation torque of the polishing table;
a surface temperature of the polishing pad; and
a condition of the polishing pad.

4. The information processing apparatus according to claim 1, wherein the polishing-fluid-supply-nozzle state information included in the operating condition information includes at least one of:
a flow rate of the polishing fluid;
a dropping position of the polishing fluid;
a temperature of the polishing fluid;
a concentration of the polishing fluid; and
a cleanliness of the polishing fluid.

5. The information processing apparatus according to claim 1, wherein the dresser includes the dresser disk configured to be moved by a rotating mechanism, a vertical movement mechanism, and an oscillation mechanism, and
the dresser state information included in the operating condition information includes at least one of:
a rotation speed of the dresser;
a rotation torque of the dresser;
an oscillation position of the dresser;
an oscillation speed of the dresser;
an oscillation torque of the dresser;
a height of the dresser;
a pressing load when the dresser disk is brought into contact with the polishing pad; and
a condition of the dresser disk.

6. The information processing apparatus according to claim 1, wherein the atomizer state information included in the operating condition information includes at least one of:
a flow rate of the cleaning fluid;
a dropping position of the cleaning fluid; and
a pressure of the cleaning fluid.

7. The information processing apparatus according to claim 1, wherein the operating condition information further includes:
device internal-environment information indicating environment of a space in which the chemical mechanical polishing is performed, and
the device internal-environment information included in the operating condition information includes at least one of:
temperature of the space;
humidity of the space;
atmospheric pressure of the space;
airflow of the space;
an oxygen concentration of the space; and
sound of the space.

8. The information processing apparatus according to claim 1, wherein the operating condition information further includes:
processing result information indicating a result of the chemical mechanical polishing, and
the processing result information included in the operating condition information includes the number of substrates on which the chemical mechanical polishing has been performed.

9. The information processing apparatus according to claim 1, wherein the polishing-pad state information comprises condition information indicating a condition of a polishing surface of the polishing pad, and
the condition information includes at least one of:
a distribution state of polishing debris on the polishing surface;
a flatness of the polishing surface;
a surface roughness of the polishing surface;
a temperature of the polishing surface;
a wetness of the polishing surface; and
a friction coefficient of the polishing surface.

10. The information processing apparatus according to claim 1, wherein the polishing-pad state information includes at least one of:
remaining service life information indicating a remaining service life of the polishing pad; and
polishing quality information indicating a polishing quality of the polishing pad.

11. An inference apparatus comprising:
a memory; and
a processor configured to perform:
an information acquisition process of acquiring operating condition information as operating conditions under which a substrate processing apparatus operates, the operating condition information including top-ring state information indicating a state of a top ring, polishing-table state information indicating a state of a polishing table, polishing-fluid-supply-nozzle state information indicating a state of a polishing-fluid supply nozzle, dresser state information indicating a state of a dresser, and atomizer state information indicating a state of an atomizer, the substrate processing apparatus being configured to perform chemical mechanical polishing of a substrate and including the polishing table configured to rotatably support a polishing pad, the top ring configured to press the substrate against the polishing pad, the polishing-fluid supply nozzle configured to supply a polishing fluid onto the polishing pad, the dresser configured to rotatably support a dresser disk and bring the dresser disk into contact with the polishing pad to dress the polishing pad, and the atomizer configured to emit a cleaning fluid to the polishing pad; and
an inference process of inferring polishing-pad state information indicating a state of the polishing pad when the substrate processing apparatus operates under the operating conditions indicated by the operating condition information, when the operating condition information is acquired in the information acquisition process.

12. A machine-learning apparatus comprising:
a learning-data storage section storing multiple sets of learning data including operating condition information as operating conditions under which a substrate processing apparatus operates, the operating condition information including top-ring state information indicating a state of a top ring, polishing-table state information indicating a state of a polishing table, polishing-fluid-supply-nozzle state information indicating a state of a polishing-fluid supply nozzle, dresser state information indicating a state of a dresser, and atomizer state information indicating a state of an atomizer, the multiple sets of learning data further including polishing-pad state information indicating a state of a polishing pad when the substrate processing apparatus operates under the operating conditions indicated by the operating condition information, the substrate processing apparatus being configured to perform chemical mechanical polishing of a substrate and including the polishing table configured to rotatably support the polishing pad, the top ring configured to press the substrate against the polishing pad, the polishing-fluid supply nozzle configured to supply a polishing fluid onto the polishing pad, the dresser configured to rotatably support a dresser disk and bring the dresser disk into contact with the polishing pad to dress the polishing pad, and the atomizer configured to emit a cleaning fluid to the polishing pad;
a machine-learning section configured to cause a learning model to learn a correlation between the operating condition information and the polishing-pad state information by inputting the multiple sets of learning data to the learning model; and
a learned-model storage section configured to store the learning model that has learned the correlation by the machine-learning section.

13. (canceled)

14. (canceled)

15. (canceled)
